(19) United States
(12) Patent Application Publication
(10) Pub. No.: US 2019/0064558 A1
(43) Pub. Date: Feb. 28, 2019

(54) Liquid Crystal Display Assembly and Method for Manufacturing Same

(71) Applicant: Wuhan China Star Optoelectronics Semiconductor Display Technology Co., Ltd., Wuhan, Hubei (CN)

(72) Inventor: Gaozhen Wang, Wuhan (CN)

(73) Assignee: Wuhan China Star Optoelectronics Semiconductor Dis play Technology Co., Ltd., Wuhan, Hubei (CN)

(21) Appl. No.: 15/574,189

(22) PCT Filed: Nov. 1, 2017
(86) PCT No.: PCT/CN2017/108860

§ 371 Date: Nov. 15, 2017

(30) Foreign Application Priority Data
Aug. 30, 2017 (CN) 201710763525.4

(51) Int. Cl. G02F 1/1333; G02F 1/1343; G02F 1/1335; G02F 1/1339; G02F 1/1368; G02F 1/1341; H01L 27/32

(52) U.S. Cl. CPC G02F 1/1333; G02F 1/134309; G02F 1/133528; G02F 1/1339; G02F 1/1368; G02F 2001/133612; G02F 1/133603; H01L 27/3232; G02F 2201/44; G02F 2001/133342; G02F 1/1341

(57) ABSTRACT

A liquid crystal display assembly and a method for manufacturing the same are provided in the present disclosure, that provides a first liquid crystal module, a second liquid crystal module, and an organic light emitting diode module. A thin film transistor layer of the organic light emitting diode module is directly disposed on a first substrate of the first liquid crystal module. Thus, a liquid crystal display assembly with double-sided displaying capabilities is implemented by light emitted from double-sided of the organic light emitting diode module, as well as light selected through the first liquid crystal module and the second liquid crystal module.

### FIELD OF THE INVENTION

The present disclosure relates to a technical field of liquid crystal displays, and particularly to a liquid crystal display assembly with double-sided displaying capabilities and a method for manufacturing same.

### BACKGROUND OF THE INVENTION

With development of information transmission and electronic products, displays have been widely used, wherein double-sided displays have a greatly improved application range and are mainly used for bank counters, service industry, catering industry, government services, etc. However, in the prior art, they are commonly formed by using two independent single-sided organic electro-luminescent diode display panels glued to each other, which requires a cumbersome process and a high cost. Therefore, it is necessary to provide a liquid crystal display assembly with double-sided displaying capabilities to solve problems existing in the prior art.

### SUMMARY OF THE INVENTION

An object of the present disclosure is to provide a liquid crystal display assembly with double-sided displaying capabilities and a method for manufacturing the same.

A liquid crystal display assembly, which comprises:

a first liquid crystal module comprising a first substrate, a second substrate, and a first liquid crystal layer disposed between the first substrate and the second substrate, wherein the first liquid crystal module further comprises a first electrode and a second electrode, the first electrode is adjacent to the first substrate, the second electrode is adjacent to the second substrate, and the first liquid crystal layer is disposed between the first electrode and the second electrode;
a second liquid crystal module comprising a third substrate, a fourth substrate, and a second liquid crystal layer disposed between the third substrate and the fourth substrate;
an organic light emitting diode module disposed between the first liquid crystal module and the second liquid crystal module, wherein the organic light emitting diode module comprises a thin film transistor layer and a pixel layer that is electrically connected to the thin film transistor layer on the first substrate, and the pixel layer is disposed on the third substrate; and four polarizers comprising a first polarizer, a second polarizer, a third polarizer, and a fourth polarizer, wherein the first polarizer is disposed on a side of the second substrate away from the first substrate, the second polarizer is disposed between the first substrate and the first electrode, the third polarizer is disposed between the pixel layer and the third substrate, the fourth polarizer is disposed on a side of the fourth substrate away from the third substrate.

In the liquid crystal display assembly provided in the present disclosure, the first liquid crystal module further comprises a first frame sealant disposed between the first substrate and the second substrate, the first frame sealant surrounds the first liquid crystal layer.

In the liquid crystal display assembly provided in the present disclosure, the second liquid crystal module further comprises a second frame sealant disposed between the third substrate and the fourth substrate, the second frame sealant surrounds the second liquid crystal layer.

Another liquid crystal display assembly, which comprises:

a first liquid crystal module comprising a first substrate, a second substrate, and a first liquid crystal layer disposed between the first substrate and the second substrate;
a second liquid crystal module comprising a third substrate, a fourth substrate, and a second liquid crystal layer disposed between the third substrate and the fourth substrate; and
an organic light emitting diode module disposed between the first liquid crystal module and the second liquid crystal module, wherein the organic light emitting diode module comprises a thin film transistor layer and a pixel layer electrically connected to the thin film transistor layer disposed on the first substrate, and the pixel layer is disposed on the third substrate.

In the liquid crystal display assembly provided in the present disclosure, the first liquid crystal module further comprises a first electrode and a second electrode, the first electrode is adjacent to the first substrate, the second electrode is adjacent to the second substrate, the first liquid crystal layer is disposed between the first electrode and the second electrode.

In the liquid crystal display assembly provided in the present disclosure, the first liquid crystal module further comprises a first frame sealant disposed between the first substrate and the second substrate, the first frame sealant surrounds the first liquid crystal layer.

In the liquid crystal display assembly provided in the present disclosure, the second liquid crystal module further comprises a third electrode and a fourth electrode, the third electrode is adjacent to the third substrate, the fourth electrode is adjacent to the fourth substrate, the second liquid crystal layer is disposed between the third electrode and the fourth electrode.

In the liquid crystal display assembly provided in the present disclosure, the second liquid crystal module further comprises a second frame sealant disposed between the third substrate and the fourth substrate, the second frame sealant surrounds the second liquid crystal layer.

The liquid crystal display assembly provided in the present disclosure further comprises a polarizer disposed on a side of the second substrate away from the first substrate.

The liquid crystal display assembly provided in the present disclosure further comprises a polarizer disposed between the first substrate and a first electrode.

The liquid crystal display assembly provided in the present disclosure further comprises a polarizer disposed between the pixel layer and the third substrate.

The liquid crystal display assembly provided in the present disclosure further comprises a polarizer disposed on a side of the fourth substrate away from the third substrate.

In the liquid crystal display assembly provided in the present disclosure, the first liquid crystal module further comprises a first frame sealant disposed between the first substrate and the second substrate, the first frame sealant surrounds the first liquid crystal layer.

In the liquid crystal display assembly provided in the present disclosure, the second liquid crystal module further comprises a second frame sealant disposed between the third substrate and the fourth substrate, the second frame sealant surrounds the second liquid crystal layer.

A method for manufacturing a liquid crystal display assembly, comprising:

providing a first substrate, and a thin film transistor layer on the first substrate; disposing a pixel layer on the thin film transistor layer;
disposing a third substrate on the pixel layer, disposing a polarizer on the third substrate, disposing a third electrode on the polarizer, and disposing a second liquid crystal layer on the third electrode;
disposing a fourth substrate on the second liquid crystal layer, and disposing a fourth electrode on a side of the fourth substrate toward the second liquid crystal layer;
disposing another polarizer on a side of the first substrate away from the thin film transistor layer, disposing a first electrode on a side of the another polarizer away from the first substrate, and disposing a first liquid crystal layer on a side of the first electrode away from the first substrate; and
disposing a second substrate on a side of the first liquid crystal layer away from the first substrate, and disposing a second electrode on a side of the second substrate toward the first liquid crystal layer.

In the method for manufacturing the liquid crystal display assembly provided in the present disclosure, one polarizer is disposed on a side of the second substrate away from the first liquid crystal layer.

In the method for manufacturing the liquid crystal display assembly provided in the present disclosure, one polarizer is disposed on a side of the fourth substrate away from the second liquid crystal layer.

In the method for manufacturing the liquid crystal display assembly provided in the present disclosure, the first liquid crystal module further comprises a first frame sealant disposed between the first substrate and the second substrate, the first frame sealant surrounds the first liquid crystal layer.

In the method for manufacturing the liquid crystal display assembly provided in the present disclosure, the second liquid crystal module further comprises a second frame sealant disposed between the third substrate and the fourth substrate, the second frame sealant surrounds the second liquid crystal layer.

In the liquid crystal display assembly and the method for manufacturing the same provided in the present disclosure, a first liquid crystal module, a second liquid crystal module, and an organic light emitting diode module are provided. The thin film transistor layer of the organic light emitting diode module is directly disposed on the first substrate of the first liquid crystal module. Thus, a liquid crystal display assembly with double-sided displaying capabilities is implemented by light emitted from double-sided of the organic light emitting diode module, as well as light selected through the first liquid crystal module and the second liquid crystal module.

### BRIEF DESCRIPTION OF THE DRAWINGS

FIG. 1 is a cross-sectional view of an embodiment of a liquid crystal display assembly provided by one embodiment of the present disclosure.

FIG. 2 is a cross-sectional view of another embodiment of a liquid crystal display assembly provided by one embodiment of the present disclosure.

### DETAILED DESCRIPTION OF THE PREFERRED EMBODIMENTS

A liquid crystal display assembly 10 is provided in an embodiment of the present disclosure.

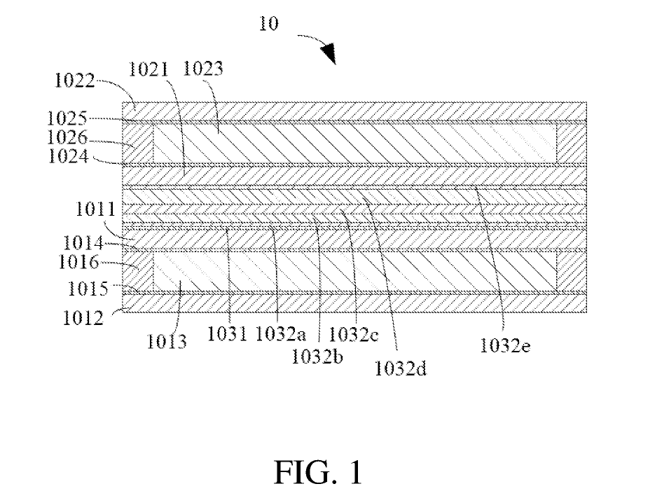

Refer to FIG. 1, the liquid crystal display assembly 10 includes a first liquid crystal module 101, a second liquid crystal module 102, and an organic light emitting diode module 103. The organic light emitting diode module 103 is disposed between the first liquid crystal module 101 and the second liquid crystal module 102.

The first liquid crystal module 101 includes a first substrate 1011, a first liquid crystal layer 1012, and a second substrate 1013. The first liquid crystal layer 1012 is disposed between the first substrate 1011 and the second substrate 1012.

In some embodiments, the first liquid crystal module 101 may further include a first electrode 1014 and a second electrode 1015. The first electrode 1014 is adjacent to the first substrate 1011. The second electrode 1015 is adjacent to the second substrate 1012. The first liquid crystal layer 1012 is disposed between the first electrode 1014 and the second electrode 1045. In some embodiments, the first liquid crystal module 101 further comprises a first frame sealant 1016. The first frame sealant 1016 is disposed between the first substrate 1011 and the second substrate 1013. The first frame sealant 1016 surrounds the first liquid crystal layer 1012.

The second liquid crystal module 102 includes a third substrate 1021, a second liquid crystal layer 1022, and a fourth substrate 1023. The second liquid crystal layer 1022 is disposed between the third substrate 1021 and the fourth substrate 1023.

In some embodiments, the second liquid crystal module 102 further includes a third electrode 1024 and a fourth electrode 1025. The third electrode 1024 is adjacent to the third substrate 1021. The fourth electrode 1021 is adjacent to the fourth substrate 1023. The second liquid crystal layer 1022 is disposed between the third electrode 1024 and the fourth electrode 1025. In some embodiments, the second liquid crystal module 102 may further include a second frame sealant 1026. The second frame sealant 1026 is disposed between the third substrate 1021 and the fourth substrate 1023. The second frame sealant 1026 surrounds the second liquid crystal layer 1022.

The organic light emitting diode module 103 includes a thin film transistor layer 1031 and a pixel layer 1032 that is electrically connected to the thin film transistor layer 1031. The thin film transistor layer 1031 is disposed on the first substrate 1011. The pixel layer 1032 is disposed on the third substrate 1021.

The pixel layer 1032 may include a fifth electrode 1032a, a first structure layer 1032b, a light emitting structure layer 1032c, a second structure layer 1032d, and a sixth electrode 1032e.

In one embodiment, the first structure layer 1032b may be an electron forming layer, the second structure layer 1032d may be a hole forming layer. In one embodiment, the first structure layer 1032b may be a hole forming layer, the second structure layer 1032d may be an electron forming layer.

In some embodiments, each of the first electrode 1014, the second electrode 1015, the third electrode 1024, the fourth electrode 1015, the fifth electrode 1032a, and the sixth electrode 1032e may be made of indium tin oxide electrode.

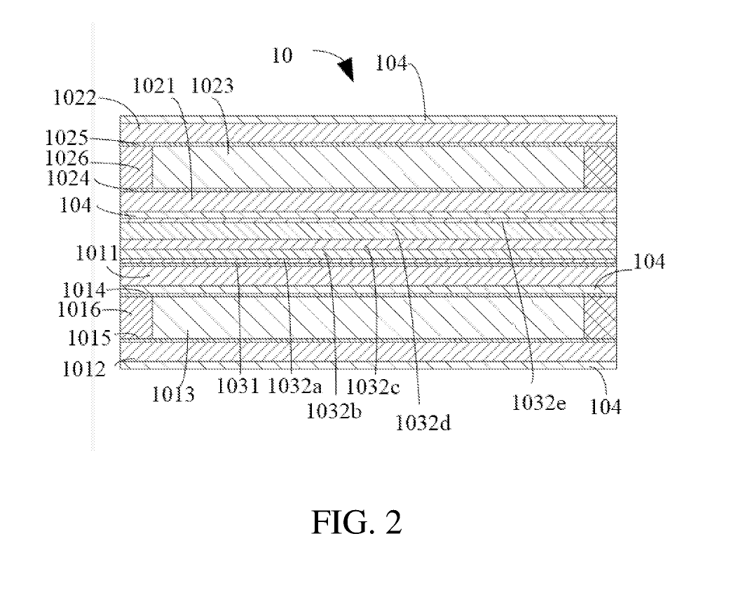

In some embodiments, refer to FIG. 2, the liquid crystal display assembly 10 may further include at least one polarizer 104. The polarizer 104 may be disposed on a side of the second substrate 1013 away from the first substrate 1011.

In some embodiments, the polarizer 104 may be disposed between the first substrate 1011 and the first electrode 1014. In some embodiments, the polarizer 104 may be disposed between the pixel layer 1032 and the third substrate 1021. In some embodiments, the polarizer 104 may be disposed on a side of the fourth substrate 1023 away from the third substrate 1021.

A method for manufacturing a liquid crystal display assembly is provided in an embodiment of the present disclosure, and includes the following steps:

providing a first substrate 101, and a thin film transistor layer 1031 disposed on the first substrate 101;
disposing a pixel layer 102 on the thin film transistor layer 1031;
disposing a third substrate 1021 on the pixel layer 102, disposing a polarizer 104 on the third substrate 1021, disposing a third electrode 1024 on the polarizer 104, and disposing a second liquid crystal layer 1022 on the third electrode 1024;
disposing a fourth substrate 1023 on the second liquid crystal layer 1022, and disposing a fourth electrode 1025 on a side of the fourth substrate 1023 toward the second liquid crystal layer 1022;
disposing another polarizer 104 on a side of the first substrate 1011 away from the thin film transistor layer 1031, disposing a first electrode 1014 on a side of the another polarizer 104 away from the first substrate 1011, and disposing a first liquid crystal layer 1012 on a side of the first electrode 1014 away from the first substrate 1011; and
disposing a second substrate 1013 on a side of the first liquid crystal layer 1012 away from the first substrate 1011, and disposing a second electrode 1015 on a side of the second substrate 1013 toward the first liquid crystal layer 1012.

In the method for manufacturing the liquid crystal display assembly 10 provided in the present disclosure, one polarizer 104 may be disposed on a side of the second substrate 1013 away from the first liquid crystal layer 1012.

In the method for manufacturing the liquid crystal display assembly 10 provided in the present disclosure, one polarizer 104 may be disposed on a side of the fourth substrate 1023 away from the second liquid crystal layer 1022.

In the method for manufacturing the liquid crystal display assembly 10 provided in the present disclosure, light emitted from the pixel layer 1032 is controlled by the thin film transistor layer 1031 of the organic light emitting diode module 103, wherein the thin film transistor layer 1031 faces the first liquid crystal module 101, the pixel layer 1032 is toward the second liquid crystal module 102. Thus, light emitted from the pixel layer 1032 simultaneously emits from a direction toward the first liquid crystal module 101 and another direction toward the second liquid crystal module 102, and the light will be applied to the first liquid crystal module 101 and the second liquid crystal module 102, respectively. Therefore, the liquid crystal current assembly emitting light from two sides can be implemented.

The liquid crystal display module provided in the embodiments of the present disclosure has been described in detail, and the principles and embodiments of the present disclosure have been described with reference to specific examples, and the description of the above embodiments is merely for the purpose of understanding the present disclosure. At the same time, the content of the specification is not to be construed as limit of the present disclosure, that is in view of detail change of the present disclosure and application scope of the present disclosure to those skilled in the art.

What is claimed is:

1. A liquid crystal display assembly, comprising:
a first liquid crystal module comprising a first substrate, a second substrate, and a first liquid crystal layer disposed between the first substrate and the second substrate, wherein the first liquid crystal module further comprises a first electrode and a second electrode, the first electrode is adjacent to the first substrate, the second electrode is adjacent to the second substrate, and the first liquid crystal layer is disposed between the first electrode and the second electrode;
a second liquid crystal module comprising a third substrate, a fourth substrate, and a second liquid crystal layer disposed between the third substrate and the fourth substrate;
an organic light emitting diode module disposed between the first liquid crystal module and the second liquid crystal module, wherein the organic light emitting diode module comprises a thin film transistor layer and a pixel layer electrically connected to the thin film transistor layer on the first substrate, and the pixel layer is disposed on the third substrate; and
four polarizers comprising a first polarizer, a second polarizer, a third polarizer, and a fourth polarizer, wherein the first polarizer is disposed on a side of the second substrate away from the first substrate, the second polarizer is disposed between the first substrate and the first electrode, the third polarizer is disposed between the pixel layer and the third substrate, the fourth polarizer is disposed on a side of the fourth substrate away from the third substrate.

2. The liquid crystal display assembly as claimed in claim 1, wherein the first liquid crystal module further comprises a first frame sealant disposed between the first substrate and the second substrate, the first frame sealant surrounds the first liquid crystal layer.

3. The liquid crystal display assembly as claimed in claim 1, wherein the second liquid crystal module further comprises a second frame sealant disposed between the third substrate and the fourth substrate, the second frame sealant surrounds the second liquid crystal layer.

4. A liquid crystal display assembly, comprising:
a first liquid crystal module comprising a first substrate, a second substrate, and a first liquid crystal layer disposed between the first substrate and the second substrate;
a second liquid crystal module comprising a third substrate, a fourth substrate, and a second liquid crystal layer disposed between the third substrate and the fourth substrate; and
an organic light emitting diode module disposed between the first liquid crystal module and the second liquid crystal module, wherein the organic light emitting diode module comprises a thin film transistor layer and a pixel layer electrically connected to the thin film transistor layer disposed on the first substrate, and the pixel layer is disposed on the third substrate.

5. The liquid crystal display assembly as claimed in claim 4, wherein the first liquid crystal module further comprises a first electrode and a second electrode, the first electrode is adjacent to the first substrate, the second electrode is adjacent to the second substrate, the first liquid crystal layer is disposed between the first electrode and the second electrode.

6. The liquid crystal display assembly as claimed in claim 4, wherein the second liquid crystal module further comprises a third electrode and a fourth electrode, the third electrode is adjacent to the third substrate, the fourth electrode is adjacent to the fourth substrate, the second liquid crystal layer is disposed between the third electrode and the fourth electrode.

7. The liquid crystal display assembly as claimed in claim 4, further comprising a polarizer disposed on a side of the second substrate away from the first substrate.

8. The liquid crystal display assembly as claimed in claim 4, further comprising a polarizer disposed between the first substrate and a first electrode.

9. The liquid crystal display assembly as claimed in claim 4, further comprising a polarizer disposed between the pixel layer and the third substrate.

10. The liquid crystal display assembly as claimed in claim 4, further comprising a polarizer disposed on a side of the fourth substrate away from the third substrate.

11. The liquid crystal display assembly as claimed in claim 4, wherein the first liquid crystal module further comprises a first frame sealant disposed between the first substrate and the second substrate, the first frame sealant surrounds the first liquid crystal layer.

12. The liquid crystal display assembly as claimed in claim 4, wherein the second liquid crystal module further comprises a second frame sealant disposed between the third substrate and the fourth substrate, the second frame sealant surrounds the second liquid crystal layer.

13. A method for manufacturing a liquid crystal display assembly, comprising:
providing a first substrate, and a thin film transistor layer on the first substrate;
disposing a pixel layer on the thin film transistor layer;
disposing a third substrate on the pixel layer, disposing a polarizer on the third substrate, disposing a third electrode on the polarizer, and disposing a second liquid crystal layer on the third electrode;
disposing a fourth substrate on the second liquid crystal layer, and disposing a fourth electrode on a side of the fourth substrate toward the second liquid crystal layer;
disposing another polarizer on a side of the first substrate away from the thin film transistor layer, disposing a first electrode on a side of the another polarizer away from the first substrate, and disposing a first liquid crystal layer on a side of the first electrode away from the first substrate; and
disposing a second substrate on a side of the first liquid crystal layer away from the first substrate, and disposing a second electrode on a side of the second substrate toward the first liquid crystal layer.

14. The method for manufacturing a liquid crystal display assembly as claimed in claim 13, wherein one polarizer is disposed on a side of the second substrate away from the first liquid crystal layer.

15. The method for manufacturing a liquid crystal display assembly as claimed in claim 13, wherein one polarizer is disposed on a side of the fourth substrate away from the second liquid crystal layer.

16. The method for manufacturing a liquid crystal display assembly as claimed in claim 13, wherein the first liquid crystal module further comprises a first frame sealant disposed between the first substrate and the second substrate, the first frame sealant surrounds the first liquid crystal layer.

17. The method for manufacturing a liquid crystal display assembly as claimed in claim 13, wherein the second liquid crystal module further comprises a second frame sealant disposed between the third substrate and the fourth substrate, the second frame sealant surrounds the second liquid crystal layer.
